(19) United States
(12) Patent Application Publication
(10) Pub. No.: US 2008/0143401 A1
(43) Pub. Date: Jun. 19, 2008

(54) CHARGE PUMP CIRCUIT

(75) Inventors: Toshiki Rai, Ogaki-shi (JP); Sadao Yoshikawa, Yoro-gun (JP)

Correspondence Address: MORRISON & FOERSTER LLP, 1650 TYSONS BOULEVARD, SUITE 400, MCLEAN, VA, 22102, US

(73) Assignees: Sanyo Electric Co., Ltd.; Sanyo Semiconductor Co., Ltd.

(21) Appl. No.: 11/927,095

(22) Filed: Oct. 29, 2007

(30) Foreign Application Priority Data
Oct. 31, 2006 (JP) 2006-295100

(51) Int. Cl. H03L 7/06

(52) U.S. Cl. 327/157

(57) ABSTRACT

This invention offers a charge pump circuit that solves problems of deterioration of a device (a capacitive device or a charge transfer device) composing the charge pump circuit caused by leftover charges and malfunctioning due to the leftover charges. N-channel type charge transfer MOS transistors T₀-T_{M}, each of which has a gate and a drain connected together, are connected in series between an input terminal IN and an output terminal OUT. A terminal of each of capacitive devices C₁-C_{M} is connected to each of connecting nodes A-X between the charge transfer MOS transistors, respectively. Each of the nodes A-X is connected with a voltage reduction circuit through each of N-channel type MOS transistors N₁-N_{M}, each of which has a gate and a drain connected together. That is, the charge pump circuit has paths to release the leftover charges actively from the nodes A-X to outside when a boosting operation of the charge pump circuit is terminated.

### CROSS-REFERENCE OF THE INVENTION

This application claims priority from Japanese Patent Application No. 2006-295100, the content of which is incorporated herein by reference in its entirety.

### BACKGROUND OF THE INVENTION

1. Field of the Invention

This invention relates to a charge pump circuit that generates a high voltage from a low voltage, specifically to a charge pump circuit provided with a voltage reduction circuit.

2. Description of the Related Art

A non-volatile semiconductor memory device such as an EEPROM (Electrically Programmable Read Only Memory) is required to provide memory cells with a positive high voltage (or a negative high voltage) that is higher than a power supply voltage. In such a case, where the high voltage is required, a method to integrate a charge pump circuit in the device is widely used.

FIG. 3 is a circuit diagram of a conventional charge pump circuit. The charge pump circuit boosts an input voltage Vin (=Vcc), which is inputted to an input terminal IN, to a high voltage HV that is outputted from an output terminal OUT as an output voltage Vout. N-channel type charge transfer MOS transistors T₀-T_{M} (M is an arbitrary number.), each having a gate and a drain connected together, are connected in series between the input terminal IN and the output terminal OUT. Connecting nodes, each of which is a connecting node between neighboring two of the charge transfer MOS transistors T₀-T_{M}, are called A-X.

A terminal of each of capacitive devices C₁-C_{M} is connected to each of the connecting nodes A-X, respectively. Either a first clock signal CLK or a second clock signal *CLK, which is an inverted-phase signal of the first clock signal CLK, is connected alternately to another terminal of each of the capacitive devices C₁-C_{M}.

When the power supply voltage VCC is applied to the input terminal IN and the first and second clocks CLK and *CLK are applied to the capacitive devices C1-C_{M}, the high voltage HV that is higher than the input voltage VCC can be obtained as the output voltage Vout from the output terminal OUT that is a source of the MOS transistor T_{M} in a last stage. As M denotes the number of stages in the charge pump circuit, the high voltage HV is represented by an equation:

HV=(M+1)×VCC.

### Note that a voltage loss due to the charge transfer MOS transistors T₀-T_{M} is neglected.

The output terminal OUT of the charge pump circuit is connected with a voltage reduction circuit 100. The voltage reduction circuit 100 serves to reduce the high voltage HV generated at the output terminal OUT down to a level of the power supply voltage VCC after the boosting operation by the charge pump circuit is terminated by stopping the first and second clock signals CLK and *CLK.

The technology mentioned above is described in Japanese Patent Application Publication No. 2006-229755, for example.

Because current paths are disconnected when the boosting operation is terminated, some amount of electric charges are left at each of the nodes A-X in the charge pump circuit described above. The leftover charges are spontaneously discharged as time goes on. However, the leftover charges are likely to cause two problems which are described below.

A first problem is as follows. When there is a large amount of leftover charges, it is not easily discharged spontaneously. That there is a large amount of leftover charges at the nodes A-X means that there is caused a load of high voltage imposed on the capacitive devices C₁-C_{M} and the charge transfer MOS transistors T₀-T_{M}. Because the later the stage is, the higher the voltage is boosted in the charge pump circuit, it is considered that the load of the high voltage is particularly heavy on the devices in the later stages. As a result, there is caused a problem that the capacitive devices C₁-C_{M} and the charge transfer MOS transistors T₀-T_{M} are deteriorated by the leftover charges.

A second problem is as follows. There is a case in which the boosting operation is once terminated and restarted shortly after that. An example is an instantaneous power outage. In such a case, the spontaneous discharge is not completed in time, and some leftover charges remain within the charge pump circuit. Thus, the charge pump begins its operation while it is in an un-initialized and unstable state. As a result, there is caused a problem that the charge pump circuit malfunctions and the desired level of high voltage is not outputted.

Note that these problems are not limited to the charge pump circuit which steps up the input voltage as described above, and may be also caused in a charge pump circuit which steps down the input voltage.

This invention is directed to offer a charge pump circuit that can solve the problem of the deterioration of the devices such as the capacitive devices and the charge transfer devices constituting the charge pump circuit caused by the leftover charges and the problem of the malfunctioning due to the leftover charges.

### SUMMARY OF THE INVENTION

This invention is directed to solve the problems addressed above and has following features. This invention offers a charge pump circuit having a plurality of charge transfer devices connected in series between an input terminal and an output terminal, a plurality of capacitive devices each having a terminal connected with a connecting node between each pair of the neighboring charge transfer devices and another terminal being provided with a clock signal, a voltage reduction circuit that reduces a voltage at the output terminal when the clock signal is halted and a rectifying device connected between the connecting node and the output terminal.

This invention also offers the charge pump circuit further having a first transistor that is turned on and off in response to a control signal and a second transistor that is connected in series with the first transistor and is turned off when the voltage at the output terminal is reduced to a predetermined voltage.

### BRIEF DESCRIPTION OF THE DRAWINGS

FIG. 1 is a circuit diagram showing a charge pump circuit according to an embodiment of this invention.

FIG. 2 is a timing chart showing an operation of the charge pump circuit according to the embodiment of this invention.

FIG. 3 is a circuit diagram showing a conventional charge pump circuit.

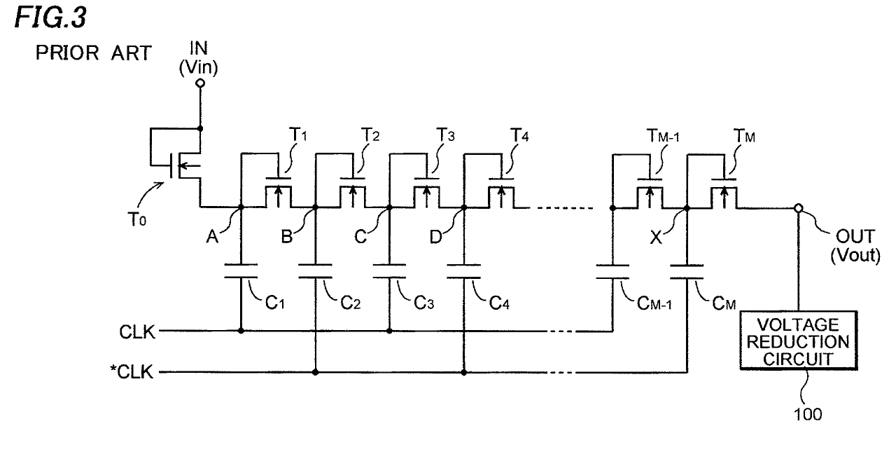

### DETAILED DESCRIPTION OF THE INVENTION

An embodiment of this invention will be explained hereinafter, referring to the drawings.

A charge pump circuit according to the embodiment of this invention boosts an input voltage Vin=VCC (3 volts, for example) inputted to an input terminal IN and outputs a high voltage HV (20 volts, for example) from an output terminal OUT as an output voltage Vout. N-channel type charge transfer MOS transistors T₀-T_{M}, each having a gate and a drain connected together, are connected in series between the input terminal IN and the output terminal OUT. Here, M is an arbitrary number. Connecting nodes, each of which is a connecting node between neighboring two of the charge transfer MOS transistors T₀-T_{M}, are called A-X.

A terminal of each of capacitive devices C₁-C_{M} is connected to each of the connecting nodes A-X, respectively. That is, a plurality of blocks each composed of the charge transfer MOS transistor and the capacitive device is connected in series. Either a first clock signal CLK1 or a second clock signal *CLK1 that is an inverted-phase signal of the first clock signal CLK1 is connected to another terminal of each of the capacitive devices C₁-C_{M}. To describe more in detail, the first clock signal CLK1 is applied to the capacitive devices C₁, C₃, - - - , C_{M-1}, while the second clock signal *CLK1 is applied to the capacitive devices C₂, C₄, - - - , C_{M}.

A NAND circuit 10 controls an operation of the charge pump circuit, and has a first input terminal to which a clock signal CLK is inputted and a second input terminal to which an enable signal ENB is inputted. The clock signal CLK is a signal to control charging and discharging of the capacitive devices C₁-C_{M}. The enable signal ENB controls turning on and off of the charge pump circuit as a whole. When the enable signal ENB is at a high (H) level, the clock signal CLK is applied to the capacitive devices C₁-C_{M} through the NAND circuit 10, and the charge pump circuit is put into operation. When the enable signal ENB is at a low (L) level, an output of the NAND circuit 10 is fixed to a high (H) level, and the charge pump circuit halts its operation.

That is, when the enable signal ENB is at the high (H) level, the first clock signal CLK1 is outputted from an output terminal of the NAND circuit 10. Also, the second clock signal *CLK1 is outputted from the output terminal of the NAND circuit 10 through an inverter 11.

The output terminal OUT of the charge pump circuit is connected with a regulator circuit 20. The regulator circuit 20 adjusts the boosted high voltage HV (20 volts, for example) to a desired voltage (about 10-12 volts, for example). A zener diode may be used as the regulator circuit 20, for example. The voltage adjusted by the regulator circuit 20 is supplied to a load such as memory cells (not shown).

The output terminal OUT of the charge pump circuit is also connected with a voltage reduction circuit 30. The voltage reduction circuit 30 reduces the high voltage HV generated at the output terminal OUT to a predetermined level (a level of the power supply voltage VCC, for example) in response to a control signal Ctrl after the application of the clock signal CLK is halted and the boosting operation by the charge pump circuit is terminated.

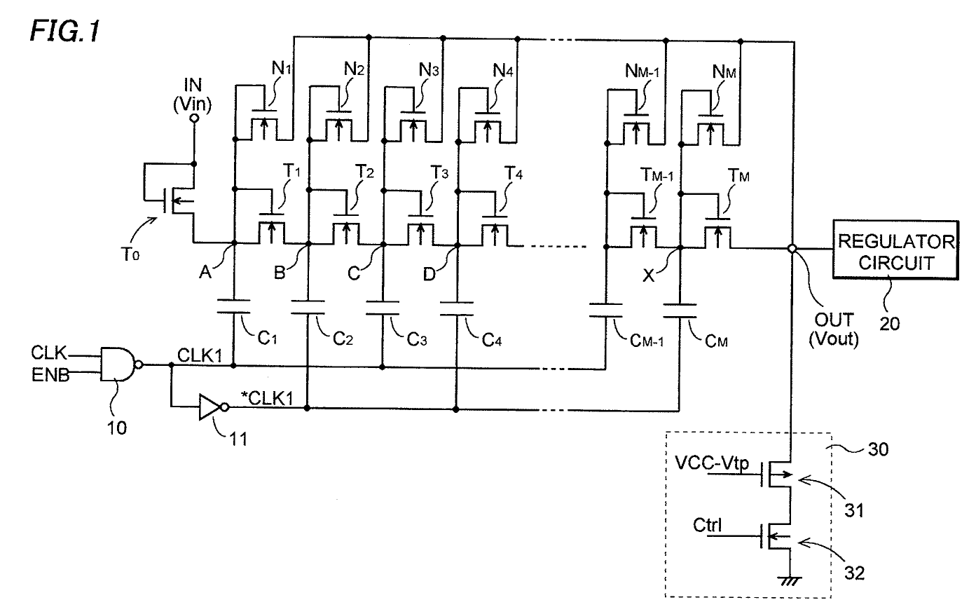

The voltage reduction circuit 30 is composed of a P-channel type MOS transistor 31 and an N-channel type MOS transistor 32 connected in series between the output terminal OUT and a ground terminal GND as shown in FIG. 1, for example. A voltage VCC−Vtp, which is the power supply voltage VCC minus a threshold voltage of the P-channel type MOS transistor 31, is applied to a gate of the P-channel type MOS transistor 31 so that the P-channel type MOS transistor 31 is turned off when the voltage at the output terminal OUT is equal to or less than VCC. The control signal Ctrl, which is for controlling the voltage reduction circuit 30, is applied to a gate of the N-channel type MOS transistor 32.

Each of the nodes A-X is connected with the output terminal OUT through each of N-channel type MOS transistors N₁-N_{M}, which has a gate and a drain connected together. The MOS transistors N₁-N_{M} are rectifying devices through each of which a current flows from each of the nodes A-X to the voltage reduction circuit 30 and make paths to release leftover charges remaining at the nodes A-X after the operation of the charge pump is terminated.

It is preferable that a size of the MOS transistors N₁-N_{M} is smaller than a size of the charge transfer MOS transistors T₀-T_{M}. Here, the size of the transistor means W/L, where W represents a gate width and L represents a gate length of the transistor. Also, it is preferable that a parasitic capacitance of each of the MOS transistors N₁-N_{M} is much smaller than a parasitic capacitance of each of the charge transfer MOS transistors T₀-T_{M} and a capacitance of each of the capacitive devices C₁-C_{M}. The reason for the above is to prevent an efficiency of the boosting operation of the charge pump circuit from being reduced because of charges stored in the parasitic capacitances of the MOS transistors N₁-N_{M}. The parasitic capacitance of the MOS transistor mentioned above means a sum of a gate capacitance, junction capacitances of PN junctions between source and drain layers and a substrate and the like.

It is preferable that the sources of the MOS transistors N₁-N_{M} are connected with the voltage reduction circuit 30, as shown in FIG. 1. It is because a structure of the charge pump circuit can be simplified by realizing the reduction of the high voltage generated at the output terminal OUT to the level of the power supply voltage VCC and releasing the leftover charges at the nodes A-X with the voltage reduction circuit 30 only. Note that no current flows from the output terminal OUT to the nodes A-X because of rectification of the MOS transistors N₁-N_{M}. Although it is possible to replace the MOS transistors N₁-N_{M} with other rectifying devices such as PN junction diodes, it is preferable to adopt the MOS transistors from a standpoint of size reduction of the device.

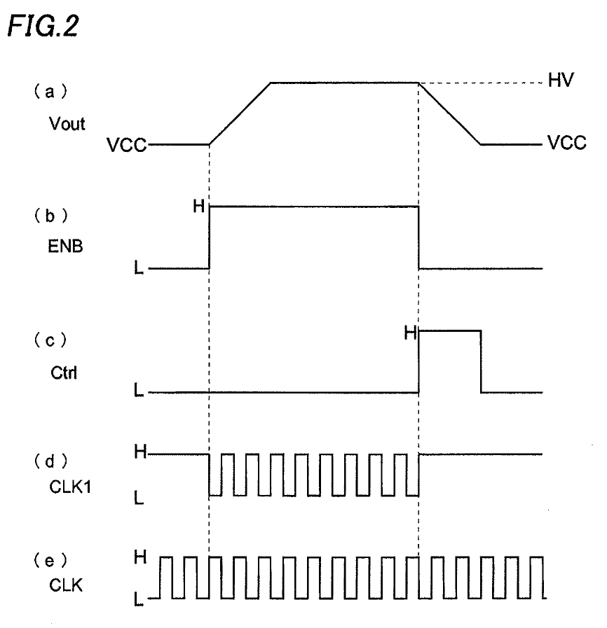

Next, an operation of the charge pump circuit structured as described above will be explained referring to operational timing chart shown in FIG. 2.

First, during a period in which the enable signal ENB is at a the low level, the boosting operation of the charge pump circuit does not take place and the output voltage Vout at the output terminal OUT is at the level of VCC (Refer to (a) and (b) in FIG. 2.).

Next, when the enable signal ENB is turned to the high level, the first clock signal CLK1 that corresponds to the clock signal CLK is outputted from the NAND circuit 10 and applied to the capacitive devices C₁, C₃, - - - , C_{M-1} (Refer to (d) in FIG. 2.). Also, the second clock signal *CLK1 that is the inversion of the first clock signal CLK1 is applied to the capacitive devices C₂, C₄, - - - , C_{M}.

With this, the charge transfer MOS transistors T₁-T_{M} alternate between turning on and turning off, while the capacitive devices C₁-C_{M} alternate between being charged and being discharged. The charges are transferred toward the MOS transistor in a subsequent stage, and the boosted high voltage HV is outputted from the output terminal OUT as the output voltage Vout (Refer to (a) in FIG. 2.).

Next, when the enable signal ENB turns to the low level, the first clock signal CLK1 is kept at the high level and the boosting operation of the charge pump circuit is terminated (Refer to (b) and (d) in FIG. 2.).

Next, when the control signal Ctrl turns to the high level, the N-channel type MOS transistor 32 is turned on and the voltage reduction circuit 30 is put into operation. And a current flows from the output terminal OUT to the ground terminal. The P-channel type MOS transistor 31 continues to be turned on until the voltage at the output terminal OUT is reduced from the high voltage HV to the power supply voltage VCC. When the voltage at the output terminal OUT is reduced to the power supply voltage VCC, the P-channel type MOS transistor 31 is turned off and the operation of the voltage reduction circuit 30 is terminated.

The nodes A-X are connected with the voltage reduction circuit 30 through the MOS transistors N₁-N_{M}. Therefore, the leftover charges at each of the nodes A-X are moved through each of the MOS transistors N₁-N_{M} toward the voltage reduction circuit 30 and discharged in the voltage reduction circuit 30. Releasing the leftover charges at each of the nodes A-X continues until the voltage at each of the nodes A-X reaches the level of VCC.

As described above, the charge pump circuit according to the embodiment of this invention has the paths to release the leftover charges actively from the nodes A-X to outside (the voltage reduction circuit 30) when the boosting operation of the charge pump circuit is terminated. As a result, the problems of the deterioration of the devices and the malfunctioning due to the leftover charges existed with the conventional circuit are resolved.

It is apparent that this invention is not limited to the embodiment described above and a design of the circuit may be modified within the scope of the invention. For example, although the MOS transistors are used as the charge transfer devices in the embodiment described above, it is possible to use bipolar transistors instead. Also, although the voltage reduction circuit 30 reduces the output voltage down to the level of the power supply voltage VCC in the embodiment described above, the structure of the voltage reduction circuit may be changed so as to reduce the output voltage down to a different level. Also, although the charge pump circuit that steps up the input voltage is used in the embodiment described above, a charge pump circuit that steps down the input voltage may be used as well. This invention may be applied to a wide range of charge pump circuits.

With the charge pump circuit according to the embodiment of this invention, the electric charges at the connecting nodes can be actively released to the voltage reduction circuit, since the rectifying devices are placed between the charge transfer devices and the output terminal. As a result, the leftover charges do not become excessive and the problems of the deterioration of the device and the malfunctioning due to the leftover charges existed with the conventional circuit are resolved.

What is claimed is:

1. A charge pump circuit comprising:
a plurality of charge transfer devices connected in series between an input terminal and an output terminal;
a plurality of capacitive devices, each of the capacitive devices comprising a first terminal connected to a connecting node between a corresponding pair of neighboring charge transfer devices and a second terminal receiving a corresponding clock signal;
a voltage reduction circuit configured to reduce a voltage at the output terminal when the clock signal is halted; and
a rectifying device connected between the output terminal and one of the connecting nodes.

2. The charge pump circuit of claim 1, wherein the voltage reduction circuit comprises a first transistor configured to be turned on or off in response to a control signal and a second transistor connected in series with the first transistor and configured to be turned off when the voltage at the output terminal is reduced to a predetermined voltage.

3. The charge pump circuit of claim 1, wherein each of the charge transfer devices comprises a first MOS transistor comprising a gate and a drain connected to each other, and the rectifying device comprises a second MOS transistor comprising a gate and a drain connected to each other.

4. The charge pump circuit of claim 3, wherein a ratio of a channel width to a channel length of the second MOS transistor is smaller than a ratio of a channel width to a channel length of the first MOS transistor.

5. The charge pump circuit of claim 3, wherein a parasitic capacitance of the second MOS transistor is smaller than a capacitance of a corresponding capacitive device and is smaller than a parasitic capacitance of the first MOS transistor.

6. A charge pump circuit comprising:
a plurality of charge transfer devices connected in series between an input terminal and an output terminal;
a plurality of capacitive devices, each of the capacitive devices comprising a first terminal connected to a connecting node between a corresponding pair of neighboring charge transfer devices and a second terminal receiving a corresponding clock signal;
a plurality of rectifying device, each of the rectifying device connected between the output terminal and a corresponding connecting node between a pair of neighboring charge transfer devices; and
a voltage reduction circuit configured to reduce a voltage at the output terminal when the clock signal is halted.
